(19) United States
(12) Patent Application Publication
(10) Pub. No.: US 2017/0196095 A1
(43) Pub. Date: Jul. 6, 2017

(54) CIRCUIT BOARD AND MANUFACTURING METHOD THEREOF

(71) Applicant: Unimicron Technology Corp., Taoyuan City (TW)

(72) Inventors: Hung-Lin Chang, Taoyuan City (TW); Chen-Wei Tseng, New Taipei City (TW)

(21) Appl. No.: 15/058,138

(22) Filed: Mar. 1, 2016

(30) Foreign Application Priority Data
Jan. 6, 2016 (TW) 105100300

(51) Int. Cl. H05K 3/46; H05K 1/09; H05K 1/02

(52) U.S. Cl. CPC H05K 3/4679; H05K 1/0298; H05K 1/09; H05K 1/0266

(57) ABSTRACT

A circuit board includes a core layer, at least one metal contraposition component and at least one build-up circuit structure. The metal contraposition component is disposed on the core layer. The build-up circuit structure is disposed on the core layer and covers the metal contraposition component by using a position of the metal contraposition component as a fiducial mark.

### CROSS-REFERENCE TO RELATED APPLICATION

This application claims the priority benefit of Taiwan application serial no. 105100300, filed on Jan. 6, 2016. The entirety of the above-mentioned patent application is hereby incorporated by reference herein and made a part of this specification.

### BACKGROUND OF THE INVENTION

Field of the Invention

The invention relates to a circuit board and a manufacturing method thereof. More particularly, the invention relates a circuit board having low manufacturing cost and a manufacturing method thereof.

Description of Related Art

Recently, the circuit board is manufactured by laminating the build-up circuit structure on the core layer. However, in the lamination process, because alignment target points on the core layer are covered by the build-up circuit structure, the positions of the alignment target points need being found by X ray first, and then serve as positioning reference points by using the spot face method (that is drilling holes on the circuit board after lamination process). With the aforementioned alignment method, every time when a layer needs being aligned to be laminated on the circuit layer, X ray needs being used to aim at the alignment target points of the inner layer and then the spot face method is used again (that is drilling though all layers of the circuit board structure). Therefore, the greater number of circuit layers of the circuit board is needed, the greater number of times the spot face method is used. As a result, the manufacturing cost of the circuit board is increased and the manufacturing steps become more complicated.

### SUMMARY OF THE INVENTION

The invention provides a circuit board having low manufacturing cost.

The invention also provides a manufacturing method of a circuit board used to manufacture the circuit board above and having fewer processing steps, so as to reduce manufacturing time and cost.

The circuit board of the invention includes a core layer, at least one metal contraposition component, and at least one build-up circuit structure. The metal contraposition component is disposed on the core layer. The build-up circuit structure is disposed on the core layer and covers the metal contraposition component by using a position of the metal contraposition component as a fiducial mark.

In one embodiment of the invention, the core layer has an upper surface and a lower surface opposite to each other, and the metal contraposition component is disposed on the upper surface, the lower surface, or embedded in the core layer.

In one embodiment of the invention, the material of the metal contraposition component includes a magnetic metal material or a non-magnetic metal material.

In one embodiment of the invention, the metal contraposition component is located at a corner of the core layer.

The manufacturing method of the circuit board of the invention includes following steps. A core layer is provided. At least one metal contraposition component is disposed on the core layer. The position of the metal contraposition component is detected by a sensor. At least one build-up circuit structure is laminated on the core layer by using the position of the metal contraposition component as a fiducial mark.

In one embodiment of the invention, the core layer has an upper surface and a lower surface opposite to each other, and the metal contraposition component is disposed on the upper surface, the lower surface, or embedded in the core layer.

In one embodiment of the invention, the material of the metal contraposition component includes a magnetic metal material, and the sensor is a magnetic sensor.

In one embodiment of the invention, the material of the metal contraposition component includes a non-magnetic metal material, and the sensor is a metal sensor.

In one embodiment of the invention, the metal contraposition component is located at a corner of the core layer.

In one embodiment of the invention, the build-up circuit structure includes at least one patterned circuit layer and at least one dielectric layer.

Based on the above, because the position of metal contraposition component serves as the fiducial mark of the build-up circuit structure in the manufacturing method of the circuit board of the invention, in comparison with the conventional positioning method that uses X-ray and spot face method, the manufacturing method of the circuit board of the invention may effectively reduce the processing steps, so as to reduce manufacturing time and cost.

To make the above features and advantages of the invention more comprehensible, embodiments accompanied with drawings are described in detail as follows.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1A to FIG. 1D are schematic views depicting a manufacturing method of a circuit board of one embodiment of the invention.

FIG. 2 is a cross-sectional schematic view and a magnetic field line distribution view depicting a circuit board of one embodiment of the invention.

FIG. 3 is an exploded view depicting a circuit board of another embodiment of the invention.

FIG. 4 is a cross-sectional schematic view depicting the circuit board in FIG. 3 and a schematic view depicting a magnetic field line distribution generated by Eddy current.

FIG. 5A to FIG. 5E are cross-sectional schematic views depicting a manufacturing method of a circuit board of another embodiment of the invention.

### DESCRIPTION OF THE EMBODIMENTS

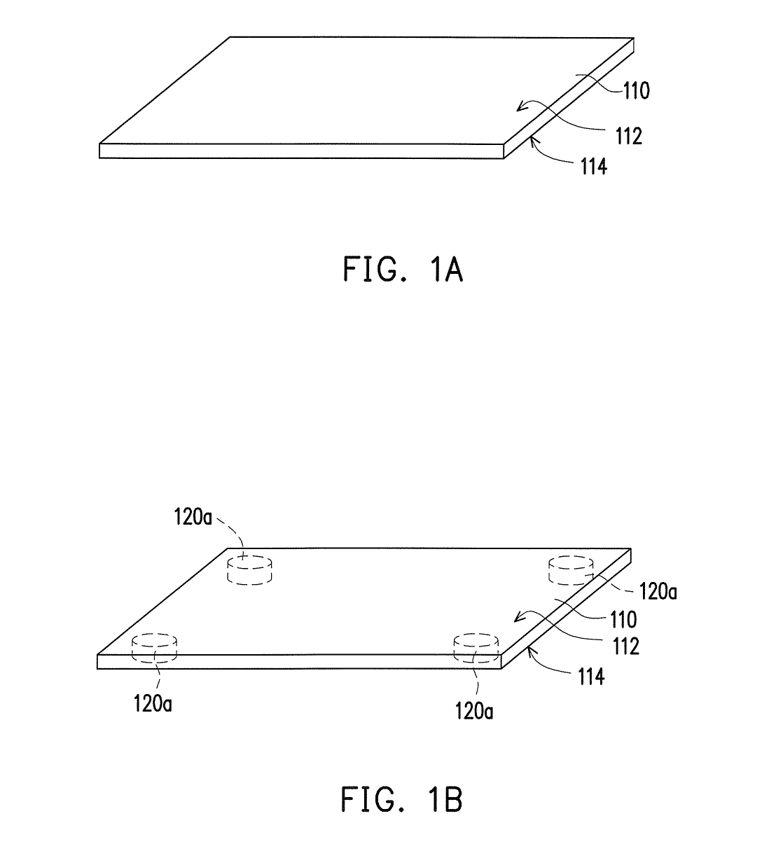

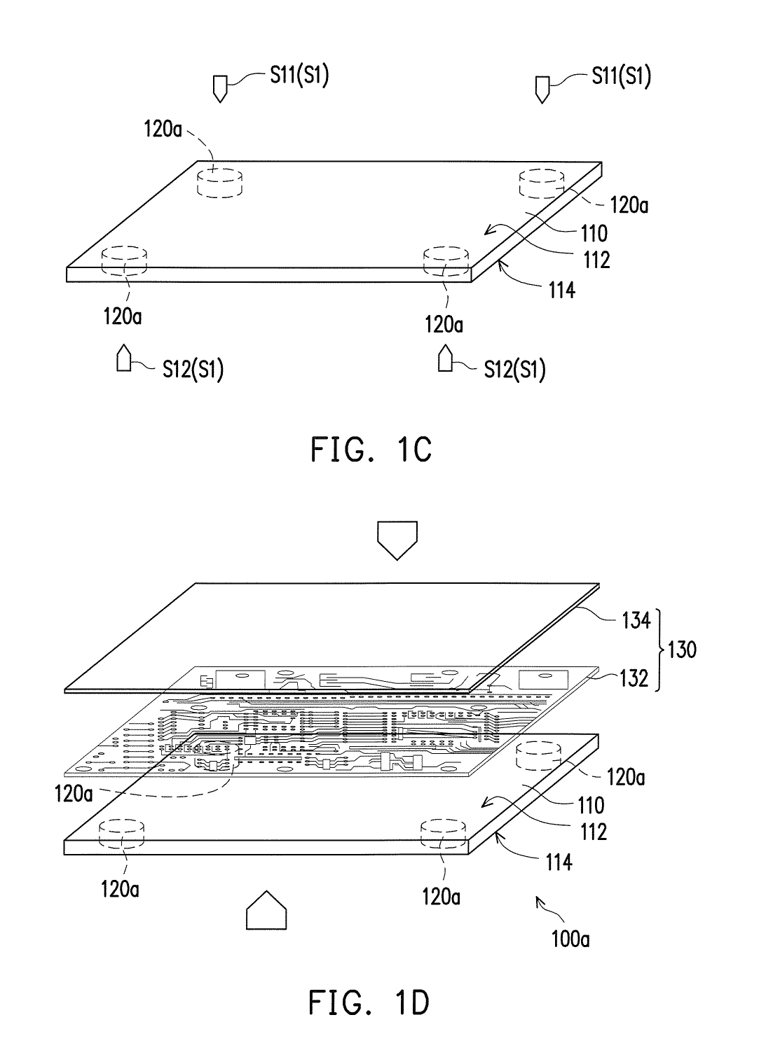

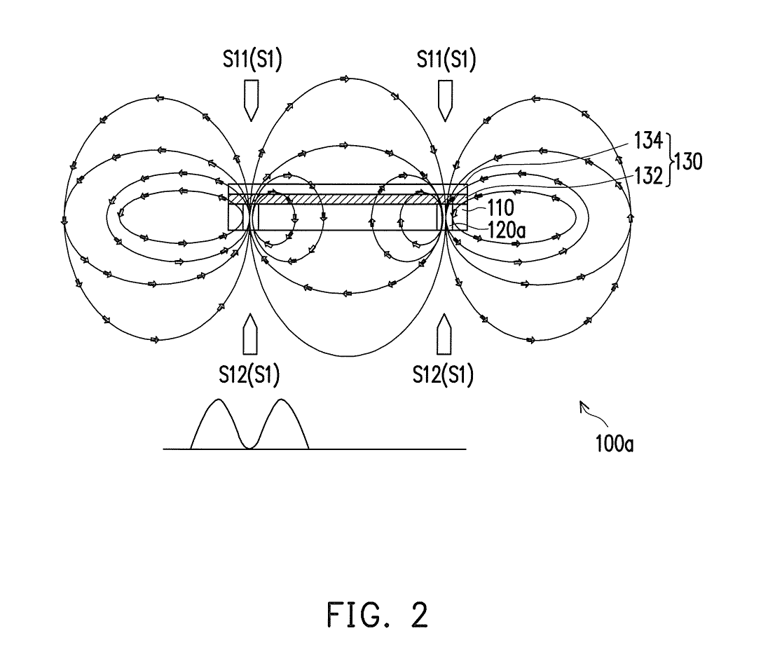

FIG. 1A to FIG. 1D are schematic views depicting a manufacturing method of a circuit board of one embodiment of the invention. FIG. 2 is a cross-sectional schematic view and a magnetic field line distribution view depicting a circuit board of one embodiment of the invention. According to the manufacturing method of the circuit board in the present embodiment, firstly, referring to FIG. 1A, a core layer 110 is provided, wherein the core layer 110 has an upper surface 112 and a lower surface 114 opposite to each other. In the present embodiment, the core layer 110 may be, for example, formed by a core dielectric layer (not shown) and patterned core conductive layers (not shown) disposed on two opposite side surfaces of the core dielectric layer; or the core layer 110 may be, for instance, a single dielectric layer, but the structure of the core layer 110 is not limited thereto.

Next, referring to FIG. 1B and FIG. 2, at least one metal contraposition component 120a (four metal contraposition components are schematically depicted in FIG. 1B) is disposed on the core layer 110. To be more specific, as shown in FIG. 1B, the metal contraposition components 120a are embedded in the core layer 110 and located at four corners of the core layer 110, so as to prevent wiring layout area of other circuit layers from being occupied by the metal contraposition components 120a. It should be noted here, when the metal contraposition component 120a is embodied as being embedded in the core layer 110, two opposite surfaces of the metal contraposition component 120a are aligned with the upper surface 112 and the lower surface 114 of the core layer 110. Certainly, in other embodiments (not shown), the metal contraposition component 120a may also be disposed at other locations in the core layer 110, such as the central area that the circuit layer is subsequently disposed; or the metal contraposition component 120a may also be disposed on the surface of the core dielectric layer of the core layer 110 or embedded in the core dielectric layer, but the invention is not limited thereto. In particular, the material of the metal contraposition component 120a in the present embodiment is embodied as a magnetic metal material, such as iron, cobalt or nickel.

Next, referring to FIG. 1C and FIG. 2, the position of the metal contraposition component 120a is detected by a sensor S1. To be more specific, the sensor S1 of the present embodiment is embodied as a magnetic sensor formed by N-pole sensors S11 and S-pole sensors S12, for example. When the sensor S1 detects the position of the metal contraposition component 120a, the magnetic pole central point of the metal contraposition component 120a is defined by the N-pole sensor S11 and the S-pole sensor S12 (for example, the distribution of magnetic field lines is analyzed by computer software, wherein the valley position in the distribution of the magnetic field lines is the position of the magnetic pole central point and is a fiducial mark).

After that, referring to FIG. 1D, at least one build-up circuit structure 130 (only one build-up circuit structure is schematically depicted in FIG. 1D) is laminated on the core layer 110 by using the position of the metal contraposition component 120a as a fiducial mark. The position of the metal contraposition component 120a is detected by the sensor S1, and then the position of the metal contraposition component 120a serves as a fiducial mark, so that the build-up circuit structure 130 may be directly laminated at a desired position on the core layer 110. As a result, the alignment between the build-up circuit structure 130 and the core layer 110 is achieved without damaging the stacked build-up circuit structure 130 and core layer 110, and the alignment precision between the build-up circuit structure 130 and the core layer 110 may be higher. Herein, the build-up circuit structure 130 of the present embodiment is embodied as including at least one patterned circuit layer 132 (only one patterned circuit layer is schematically depicted in FIG. 1D) and at least one dielectric layer 134 (only one dielectric layer is schematically depicted in FIG. 1D), but the invention is not limited thereto. It should be noted here, although it is depicted in FIG. 1D that the patterned circuit layer 132 is located between the dielectric layer 134 and the core layer 110; in other embodiments, the dielectric layer 134 may also be located between the core layer 110 and the patterned circuit layer 132, and the arrange sequence and the number of layers of the patterned circuit layer 132, the dielectric layer 134, and the core layer 110 are not limited thereto. At this time, the circuit board 100a is completely manufactured.

Structurally, referring to FIG. 2, the circuit board 100a of the present embodiment includes the core layer 110, the metal contraposition component 120a, and the build-up circuit structure 130. The metal contraposition component 120a is disposed on the core layer 110. The build-up circuit structure 130 is disposed on the core layer 110 and covers the metal contraposition component 120a by using the position of the metal contraposition component 120a as a fiducial mark. To be more specific, the metal contraposition component 120a is embedded in the core layer 110 and located at the corner of the core layer 110 in the present embodiment. The build-up circuit structure 130 is embodied as including the patterned circuit layer 132 and the dielectric layer 134 on the upper surface 112 of the core layer 110. The build-up circuit structure 130 is disposed on the core layer 110 by using the position of the metal contraposition component 120a as a fiducial mark, so that the alignment between the build-up circuit structure 130 and the core layer 110 is achieved without damaging the stacked build-up circuit structure 130 and core layer 110.

Briefly, in the present embodiment, the metal contraposition component 120a having magnetism is firstly is disposed in the core layer 110, and then the position of the metal contraposition component 120a is detected by the magnetic sensor to serve as a fiducial mark for laminating the build-up circuit structure 130 in the following step. In the present embodiment, the stronger magnetism of the metal contraposition component 120a, the greater number of the build-up circuit structures 130 may be laminated on the core layer 110. Therefore, in comparison with the conventional positioning method that needs to use X-ray and spot face method first for alignment when laminating each patterned circuit layer, the manufacturing method of the circuit board in the present embodiment may complete the alignment between the build-up circuit structure 130 and the core layer 110 without using the spot face method to damage the stacked structure and layer. Consequently, the manufacturing method of the circuit board 100a of the present embodiment may effectively reduce the processing steps, so as to reduce manufacturing cost. In addition, the circuit board 100a manufactured by the manufacturing method of the circuit board in the present embodiment may have lower manufacturing cost.

It should be noted here, the material of the metal contraposition component and the number of build-up circuit structures are not limited in the present embodiment. In FIG. 2, the material of the metal contraposition component 120a is embodied as a magnetic metal material, and the number of the build-up circuit structures 130 is embodied as one. However, in other embodiments, the material of the metal contraposition component may also be a non-magnetic metal material, and the number of the build-up circuit structures may also be a more than one.

It should be further described that the build-up by stacking method are described above as an example, actually, the sequence of the stacking technique is not limited thereto, the most important thing is that the inner and outer layers are performed coordinate aligning, so as to meet the alignment requirement of the inner and outer layers.

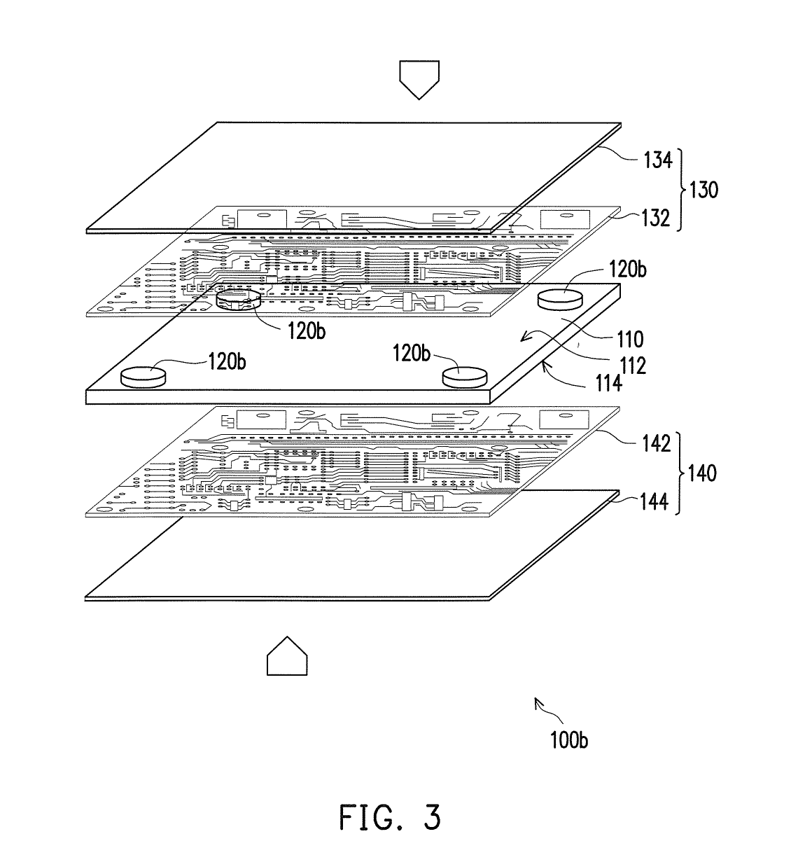

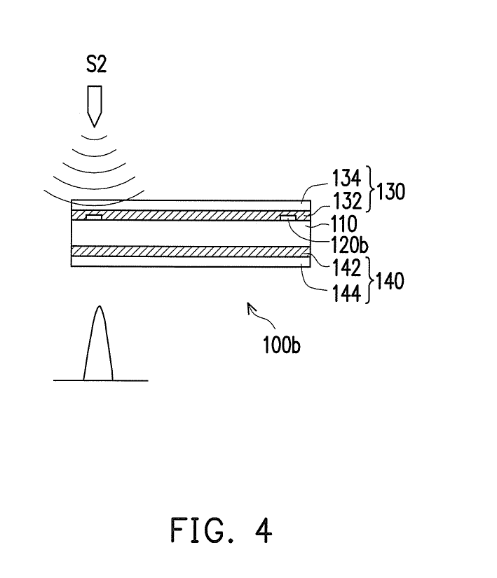

FIG. 3 is an exploded view depicting a circuit board of another embodiment of the invention. FIG. 4 is a cross-sectional schematic view depicting the circuit board in FIG. 3 and a schematic view depicting a magnetic field line distribution generated by Eddy current. Referring to FIG. 3, the circuit board 100b in the present embodiment is similar to the circuit board 100a in FIG. 2, the difference is that the material of the metal contraposition component 120b in the present embodiment is embodied as non-magnetic metal material, such as gold, silver, copper, tin, lead, aluminum, wherein the metal contraposition components 120b are disposed on the upper surface 112 of the core layer 110 and located at four corners of the core layer 110.

Furthermore, the at least one build-up circuit structure in the present embodiment is embodied as two build-up circuit structures, such as the build-up circuit structures 130 and 140 that are respectively located on the upper surface 112 and the lower surface 114 of the core layer 110, wherein the build-up circuit structure 140 also includes a patterned circuit layer 142 and a dielectric layer 144, and the patterned circuit layer 142 and the dielectric layer 144 are alternately stacked on the lower surface 114 of the core layer 110, but the arrange sequence is not limited thereto.

Referring to FIG. 4, because the material of the metal contraposition component 120b in the present embodiment is non-magnetic metal material, the position of the metal contraposition component 120b is detected by a sensor S2, such as a metal sensor, to serve as a fiducial mark for disposing the build-up circuit structures 130 and 140. It should be noted here, when the sensor S2 detects the position of the metal contraposition component 120b, the induced current (such as Eddy current) is generated in the metal contraposition component 120b by the magnetic field generated by the sensor S2, and the magnetic field generated by the Eddy current is sensed by the sensor S2 and the magnetic central point of the Eddy current is located to serve as a positioning reference points (for example, the distribution of magnetic field lines is analyzed by computer software, wherein the peak position in the distribution of the magnetic field lines is the position of the magnetic pole central point and is a fiducial mark). In comparison with the conventional positioning method that needs to use X-ray and spot face method first for alignment when laminating each patterned circuit layer, the manufacturing method of the circuit board in the present embodiment may complete the alignment between the build-up circuit structures 130 and 140, and the core layer 110 without using the spot face method to damage the stacked structure and layer. Consequently, the manufacturing method of the circuit board 100a of the present embodiment may effectively reduce the processing steps, so as to reduce manufacturing cost. In addition, the circuit board 100b manufactured by the manufacturing method of the circuit board in the present embodiment may have lower manufacturing cost.

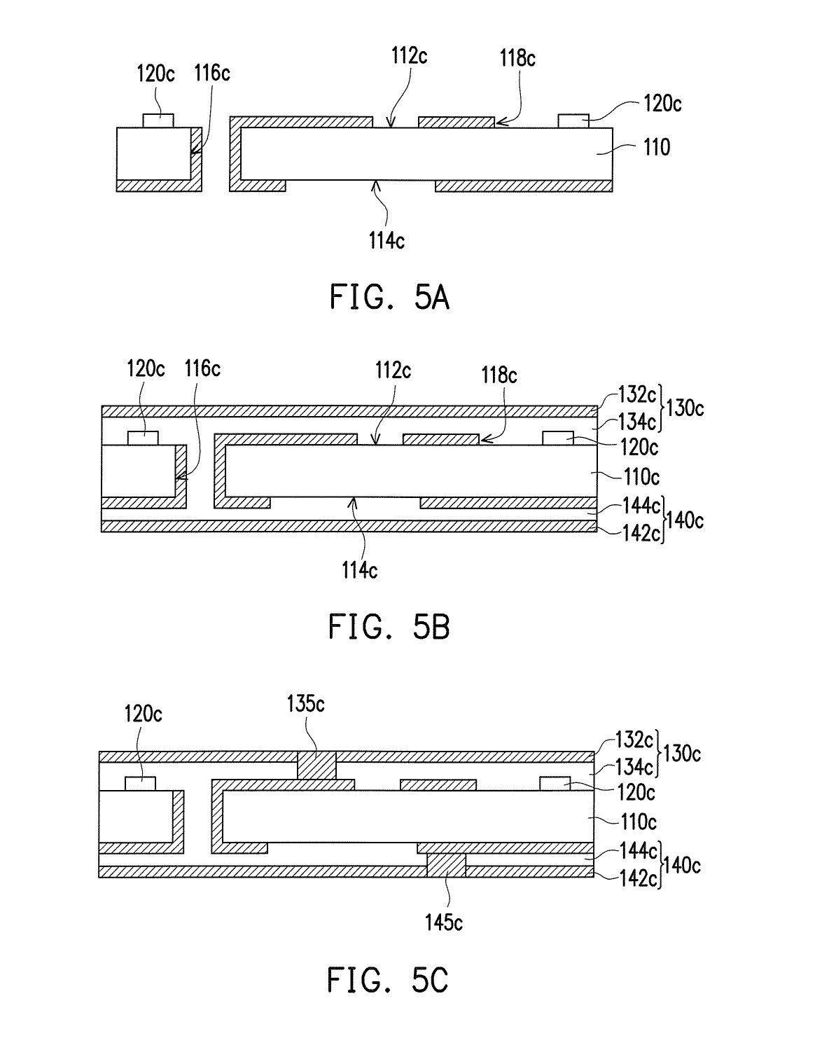

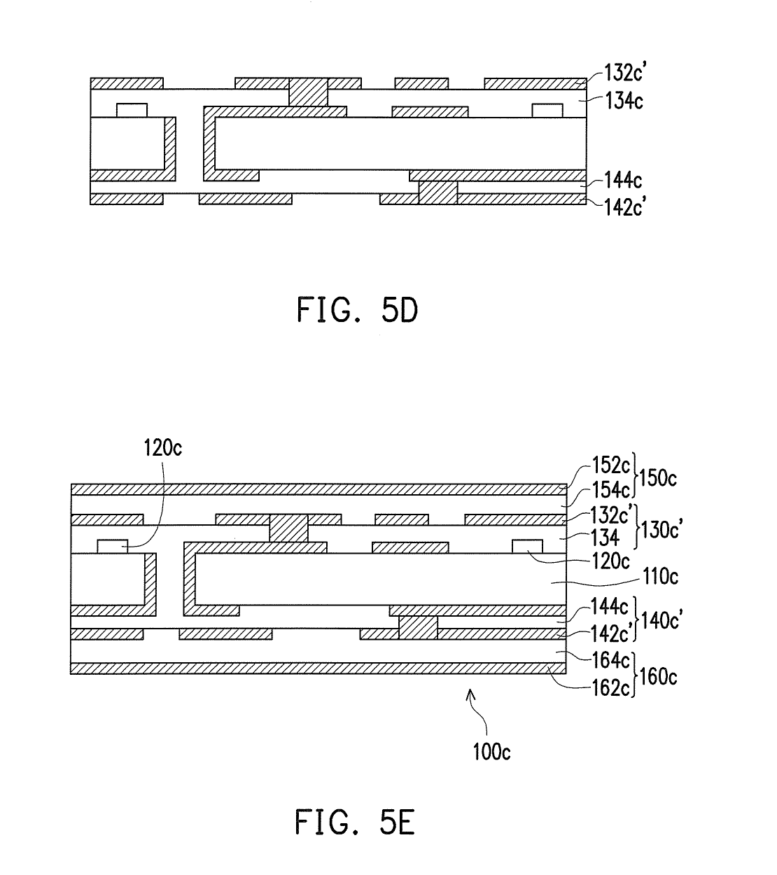

FIG. 5A to FIG. 5E are cross-sectional schematic views depicting a manufacturing method of a circuit board of another embodiment of the invention. Referring to FIG. 5A, in the manufacturing method of the circuit board of the present embodiment, firstly, a core layer 110c is provided, wherein the core layer 110c has an upper surface 112c and a lower surface 114c opposite to each other, a through hole 116c connecting the upper surface 112c and the lower surface 114c, a patterned conductive layer 118 disposed on the upper surface 112c, the lower surface 114c, and the inner wall of the through hole 116c.

Next, referring to FIG. 5A, at least one metal contraposition component 120c (a plurality of the metal contraposition components are schematically depicted in FIG. 5A) is disposed on the core layer 110c, wherein the metal contraposition component 120c is made of magnetic metal material or non-magnetic metal material, but the invention is not limited thereto. To be more specific, as shown in FIG. 5A, the metal contraposition component 120c is disposed on the upper surface 112c of the core layer 110c, but the invention is not limited thereto. In other embodiments (not shown), the metal contraposition component 120c may also be embedded in the core layer 110c, and the upper and lower surfaces of the metal contraposition component 120c may be aligned or not aligned with the upper surface 112c and the lower surface 114c of the core layer 110c.

Next, referring to FIG. 5B, at least one build-up circuit structure (only two build-up circuit structures 130c and 140c are schematically depicted in FIG. 5B) is laminated on the core layer 110c. To be more specific, the build-up circuit structure 130c is embodied as including a circuit layer 132c and a dielectric layer 134c, and the build-up circuit structure 140c is embodied as including a circuit layer 142c and a dielectric layer 144c. The dielectric layers 134c and 144c are respectively disposed on the upper surface 112c and the lower surface 114c of the core layer 110c and fill the through hole 116c up, and the circuit layers 132c and 142c are respectively located on the dielectric layers 134c and 144c. As shown in FIG. 5B, the circuit structure having four circuit layers is manufactured, but the circuit layers 132c and 142c are not patterned.

Next, referring to FIG. 5C, a sensor detects the position of the metal contraposition component 120c to serve as a fiducial mark, and a plurality of plating through holes 135c and 145c are formed on the build-up circuit structures 130c and 140c, wherein the plating through hole 135c connects the circuit layer 132c with the patterned conductive layer 118c of the core layer 110c, and the plating through hole 145c connects the circuit layer 142c with the patterned conductive layer 118c of the core layer 110c. The type of the sensor is selected according to the material of the metal contraposition component 120c, if the material of the metal contraposition component 120c is a magnetic metal material, the sensor is required to be a magnetic sensor; if the material of the metal contraposition component 120c is a non-magnetic metal material, the sensor is required to be a metal sensor.

After that, referring to FIG. 5D, the position of the metal contraposition component 120c is used as a fiducial mark to perform a patterning process on the circuit layers 132c and 142c located on the build-up circuit structures 130c and 140c, so as to form patterned circuit layers 132c′ and 142c′. At this time, the patterned circuit layers 132c′ and 142c′ expose a part of the dielectric layers 134c and 144c respectively.

Finally, referring to FIG. 5E, at least another one build-up circuit structure (only two build-up circuit structures 150c and 160c are schematically depicted in FIG. 5E) is laminated on the build-up circuit structures 130c′ and 140c′. To be more specific, the build-up circuit structure 150c is embodied as including a circuit layer 152c and a dielectric layer 154c, and the build-up circuit structure 160c is embodied as including a circuit layer 162c and a dielectric layer 164c. The dielectric layers 154c and 164c are respectively disposed on the patterned circuit layers 132c′ and 142c′ of the build-up circuit structures 130c′ and 140c′ and cover the patterned circuit layers 132c′ and 142c′, and the circuit layer 152c and 162c are respectively located on the dielectric layers 154c and 164c. As shown in FIG. 5E, the circuit structure having six circuit layers is manufactured, but the circuit layers 152c and 162c are not patterned. At this time, the circuit board 100c is completely manufactured.

It should be noted here, in other embodiments (not shown), the number of the metal contraposition components 120a, 120b, and 120c may also be one or more, therefore, the number of the metal contraposition components is not limited to a plurality of the metal contraposition components 120a, 120b, and 120c as shown in the Figures. Furthermore, the metal contraposition components 120a, 120b, and 120c may be freely disposed on the upper surfaces 112 and 112c or on the lower surfaces 114 and 114c of the core layer 110 and 110c, or embedded in the core layer 110 and 110c as long as the metal contraposition components 120a, 120b, and 120c are disposed at the core layer 110 and 110c. In addition, the number of the patterned circuit layers 132, 142, 132c′, and 142c′ of the build-up circuit structures 130, 140, 130c, and 140c and the number of the dielectric layers 134, 144, 134c, and 144c of the build-up circuit structures 130, 140, 130c, and 140c are one or more, and the arrange sequence may also be changed, the invention is not limited thereto.

In summary, because the position of metal contraposition component serves as the fiducial mark of the build-up circuit structure in the manufacturing method of the circuit board of the invention, in comparison with the conventional positioning method that uses X-ray and spot face method, the manufacturing method of the circuit board of the invention may effectively reduce the processing steps, so as to reduce manufacturing time and cost. In addition, the circuit board manufactured by the manufacturing method of the circuit board in the invention may have lower manufacturing cost.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

1. A circuit board, comprising:
a core layer;
at least one metal contraposition component, disposed on the core layer, wherein a material of the metal contraposition component is a magnetic metal material; and
at least one build-up circuit structure, disposed on the core layer and covering the metal contraposition component by using a position of the metal contraposition component as a fiducial mark.

2. The circuit board as recited in claim 1, wherein the core layer has an upper surface and a lower surface opposite to each other, and the metal contraposition component is disposed on the upper surface, the lower surface, or embedded in the core layer.

3. (canceled)

4. The circuit board as recited in claim 1, wherein the metal contraposition component is located at a corner of the core layer.

5. A manufacturing method of a circuit board, comprising:
providing a core layer;
disposing at least one metal contraposition component on the core layer;
detecting a position of the metal contraposition component by a sensor; and
laminating at least one build-up circuit structure on the core layer by using the position of the metal contraposition component as a fiducial mark.

6. The manufacturing method of the circuit board as recited in claim 5, wherein the core layer has an upper surface and a lower surface opposite to each other, and the metal contraposition component is disposed on the upper surface, the lower surface, or embedded in the core layer.

7. The manufacturing method of the circuit board as recited in claim 5, wherein a material of the metal contraposition component comprises a magnetic metal material, and the sensor is a magnetic sensor.

8. The manufacturing method of the circuit board as recited in claim 5, wherein a material of the metal contraposition component comprises a non-magnetic metal material, and the sensor is a metal sensor.

9. The manufacturing method of the circuit board as recited in claim 5, wherein the metal contraposition component is located at a corner of the core layer.

10. The manufacturing method of the circuit board as recited in claim 5, wherein the build-up circuit structure comprises at least one patterned circuit layer and at least one dielectric layer.
